(19) United States
(12) Patent Application Publication
(10) Pub. No.: US 2020/0358038 A1
(43) Pub. Date: Nov. 12, 2020

(54) FLEXIBLE ORGANIC LIGHT EMITTING DIODE DISPLAY AND MANUFACTURING METHOD THEREOF

(71) Applicant: Wuhan China Star Optoelectronics Semiconductor Display Technology Co., Ltd., Wuhan (CN)

(72) Inventors: Kerong WU, Wuhan (CN); Seungkyu CHOI, Wuhan (CN)

(73) Assignee: Wuhan China Star Optoelectronics Semiconductor Display Technology Co., Ltd., Wuhan (CN)

(21) Appl. No.: 16/640,352

(22) PCT Filed: Nov. 16, 2018
(86) PCT No.: PCT/CN2018/115894

§ 371 Date: Feb. 20, 2020

(30) Foreign Application Priority Data
Jul. 24, 2018 (CN) 201810816005.X

(51) Int. Cl. H01L 51/56; H01L 27/32; H01L 51/00

(52) U.S. Cl. CPC H01L 51/56; H01L 27/3244; H01L 2251/5338; H01L 2227/323; H01L 51/0097

(57) ABSTRACT

A method for manufacturing a flexible organic light emitting diode (OLED) display is provided, and includes steps of forming an active array layer on a flexible substrate, forming a planarization layer on the active array layer; performing photolithography on the planarization layer, to form at least a portion of an upper surface of the planarization layer into an uneven surface; forming an anode layer on the uneven surface of the planarization layer; forming an organic light emitting layer on the anode layer; forming a cathode layer on the organic light emitting layer; and forming a protective layer on the cathode layer and the planarization layer to cover the cathode layer and the planarization layer.

### FIELD OF INVENTION

The invention relates to a technical field in displays, and in particular to a flexible organic light emitting diode display and a manufacturing method thereof.

### BACKGROUND OF DISCLOSURE

With the development of display technology, although thin film transistor liquid crystal display (TFT-LCD) technology still prevails in the mainstream display market, the developments and the applications of organic light emitting diodes (OLEDs) of new generation display technology are in full swing, and OLEDs are gradually applied to many fields, such as wearable devices, like smart bracelets, smart watches, virtual reality (VR) devices, mobile phones, e-books, electronic newspapers, televisions, personal laptops, etc.

Compared with traditional TFT-LCD technology, the most significant advantage of OLEDs is that OLEDs can be made into foldable/curlable products. When a flexible OLED screen is subjected to external force, multiple bendings/curlings, or laser lift-off (LLO), the interior of the screen is subjected to uneven stresses, thereby causing local peeling in the OLED light emitting layer, as shown in FIG. 1, or even the peeling of the entire screen, as shown in FIG. 2, and greatly limiting application range and bending modes of the flexible OLED screen. As shown in FIG. 1, a film structure of the OLED product, from top to bottom, includes a thin film encapsulation (TFE), a cathode 160, and an OLED light emitting layer 150 (including an electron transport layer, an organic light emitting layer, a hole transport layer, and the like), an anode layer 140, a planarization layer (PLN), an array layer 120 (or referred to as a thin-film transistor layer), and a flexible substrate 110.

The OLED light emitting layer 150 is typically formed by layer-by-layer stacking through vacuum deposition or ink jet printing. The electron transport layer, the organic light emitting layer, and the hole transport layer of the OLED light emitting layer 150 are all organic materials. Small molecule OLED elements are formed by vacuum deposition, and it is more suitable for large molecule OLED elements to be formed by ink jet printing. However, regardless of small molecule elements or large molecular elements, adhesion between organic substances is stronger than adhesion between an organic substance and metal. Therefore, in case of folding, curling, or laser lift-off (LLO), the earliest peeled position or the easiest peeled position is the interface between the cathode layer 160 and the OLED light emitting layer 150 and the interface between the OLED light emitting layer 150 and the anode layer 140. Therefore, it is necessary and crucial to effectively enhance the adhesion between the OLED light emitting layer 150 and the upper and lower layers (cathode layer 160/anode layer 140) to prevent the OLED light emitting layer from peeling off.

Therefore, it is necessary to provide a flexible OLED display and a method for manufacturing the same to solve the problem in prior art.

### SUMMARY OF INVENTION

An object of the present disclosure is to provide a flexible organic light emitting diode display and a manufacturing method thereof, which improve the peeling occurring in the OLED light emitting layer and improve the impact resistance and the bending resistance of the flexible screen. Moreover, the solution is compatible with conventional technology.

To solve the aforementioned technical problem, a method for manufacturing a flexible organic light emitting diode display is provided in the present disclosure, including:

a step 10 of forming an active array layer on a flexible substrate, wherein a gate, a source, and a drain are formed on the active array layer;

a step 20 of forming a planarization layer on the active array layer;

a step 30 of performing photolithography on the planarization layer, to form at least a portion of an upper surface of the planarization layer into an uneven surface;

a step 40 of forming an anode layer on the uneven surface of the planarization layer;

a step 50 of forming an organic light emitting layer on the anode layer;

a step 60 of forming a cathode layer on the organic light emitting layer; and

a step 70 of forming a protective layer on the cathode layer and the planarization layer to cover the cathode layer and the planarization layer.

In an embodiment of the present disclosure, the step S30 includes a step 31 of performing the photolithography on the planarization layer, by using a photomask having a semi-transmissive array structure, to form at least the portion of the upper surface of the planarization layer into the uneven surface.

In a further feature of an embodiment provided in the present disclosure, the photomask having a semi-transmissive array structure is a half-tone photomask.

In a further feature of an embodiment provided in the present disclosure, the semi-transmissive array structure has a diameter of 1 to 2 μm.

In another embodiment provided in the present disclosure, the step S30 includes: a step 32 of performing the photolithography on the planarization layer, by using a photomask having a semi-transmissive array structure, to form the entire upper surface of the planarization layer into the uneven surface.

In an embodiment provided in the present disclosure, the step S30 includes: a step 33 of performing the photolithography on the planarization layer, to form at least the portion of the upper surface of the planarization layer into the uneven surface, and to form a via hole in the planarization layer, wherein the via hole penetrates through the planarization layer to the source and the drain.

To solve the aforementioned technical problem, a flexible organic light emitting diode display is provided in the present disclosure, and includes:

a flexible substrate;

an active array layer disposed on the flexible substrate, wherein a gate, a source and a drain formed on the active array layer;

a planarization layer disposed on the active array layer, wherein at least a portion of an upper surface of the planarization layer includes a first uneven surface;

an anode layer disposed on the first uneven surface of the planarization layer, wherein an upper surface of the anode layer includes a second uneven surface;

an organic light emitting layer disposed on the second uneven surface of the anode layer, wherein an upper surface of the organic light emitting layer includes a third uneven surface;

a cathode layer disposed on the third uneven surface of the organic light emitting layer, wherein an upper surface of the cathode layer includes a fourth uneven surface; and

a protective layer disposed on the cathode layer and the planarization layer.

In an embodiment provided in the present disclosure, only the portion of the upper surface of the planarization layer includes the first uneven surface.

In an embodiment provided in the present disclosure, the entire upper surface of the planarization layer is the first uneven surface.

In an embodiment provided in the present disclosure, the first uneven surface, the second uneven surface, the third uneven surface, and the fourth uneven surface respectively have diameters of 1 to 2 μm.

In a further feature of an embodiment provided in the present disclosure, a via hole is formed in the planarization layer, and the via hole penetrates through the planarization layer to the source or the drain.

To solve the aforementioned technical problem, a method for manufacturing a flexible organic light emitting diode display is provided in the present disclosure, and includes:

a step 10 of forming an active array layer on a flexible substrate, wherein a gate, a source, and a drain are formed on the active array layer;

a step 20 of forming a planarization layer on the active array layer;

a step 30 of performing photolithography on the planarization layer, to form at least a portion of an upper surface of the planarization layer into an uneven surface; wherein the step 30 comprises:

a step 31 of the photolithography is performed on the planarization layer, by using a photomask having a semi-transmissive array structure, to form at least the portion of the upper surface of the planarization layer into the uneven surface;

a step 40 of forming an anode layer on the uneven surface of the planarization layer;

a step 50 of forming an organic light emitting layer on the anode layer;

a step 60 of forming a cathode layer on the organic light emitting layer; and

a step 70 of forming a protective layer on the cathode layer and the planarization layer to cover the cathode layer and the planarization layer.

In an embodiment provided in the present disclosure, the photomask having a semi-transmissive array structure is a half-tone photomask.

In an embodiment provided in the present disclosure, the semi-transmissive array structure has a diameter of 1 to 2 μm.

In an embodiment provided in the present disclosure, the step S30 includes a step 32 of the photolithography is performed on the planarization layer, by using a photomask having a semi-transmissive array structure, to form the entire upper surface of the planarization layer into the uneven surface.

In an embodiment provided in the present disclosure, the step S30 includes a step 33 of performing the photolithography on the planarization layer, to form at least the portion of the upper surface of the planarization layer into the uneven surface, and to form a via hole in the planarization layer, wherein the via hole penetrates through the planarization layer to the source and the drain.

In the flexible organic light emitting diode display and the manufacturing method thereof of the present disclosure, normal flat surfaces are replaced by an uneven surface formed between the planarization layer and the anode layer, an uneven surface between the anode layer and the organic light emitting layer, and an uneven surface between the cathode layer and the organic light emitting layer, for increasing a contact area between the planarization layer and the anode layer, and a contact area between the organic light emitting layer and the cathode and the anode, thereby effectively enhancing the adhesion between the planarization layer and the anode layer and the adhesion between the OLED light emitting layer and the cathode layer and the anode layer, to improve the peeling occurring in the OLED light emitting layer, and to improve impact resistance and bending resistance of the flexible screen. At the same time, the solution is compatible with conventional technology.

### BRIEF DESCRIPTION OF DRAWINGS

The present disclosure is described herein by way of example only, with reference to the accompanying drawings as follows:

FIG. 1 illustrates local peeling occurring in an organic light emitting diode (OLED) light emitting layer in prior art.

FIG. 2 illustrates entire peeling occurring in an OLED light emitting layer in prior art.

FIG. 3 is a schematic diagram of a step 10 in a method for manufacturing a flexible OLED display in accordance with an embodiment of the present disclosure.

FIG. 4 is a schematic diagram of a step 20 in a method for manufacturing a flexible OLED display in accordance with the same embodiment of the present disclosure.

FIG. 5 is a schematic diagram of a step 31 in a method for manufacturing a flexible OLED display in accordance with the same embodiment of the present disclosure.

FIG. 6 is a schematic diagram of a step 40 in a method for manufacturing a flexible OLED display in accordance with the same embodiment of the present disclosure.

FIG. 7 is a schematic diagram of a step 50 in a method of manufacturing a flexible OLED display in accordance with the same embodiment of the present invention;

FIG. 8 is a schematic diagram of a step 60 in a method for manufacturing a flexible OLED display in accordance with the same embodiment of the present disclosure.

FIG. 9 is a schematic diagram of a step 70 in a method for manufacturing a flexible OLED display in accordance with the same embodiment of the present disclosure.

FIG. 10 is a schematic diagram of a step 32 in a method for manufacturing a flexible OLED display in accordance with another embodiment of the present disclosure.

FIG. 11 illustrates an example of a pixel design in a method for manufacturing a flexible OLED display in accordance with the same embodiment of the present disclosure.

FIG. 12 illustrates an example of a photomask used in the step 31, corresponding to the pixel design of FIG. 11, in a method for manufacturing a flexible OLED display in accordance with the same embodiment of the present disclosure.

FIG. 13 is a side view of a flexible OLED display in accordance with the same embodiment of the present disclosure.

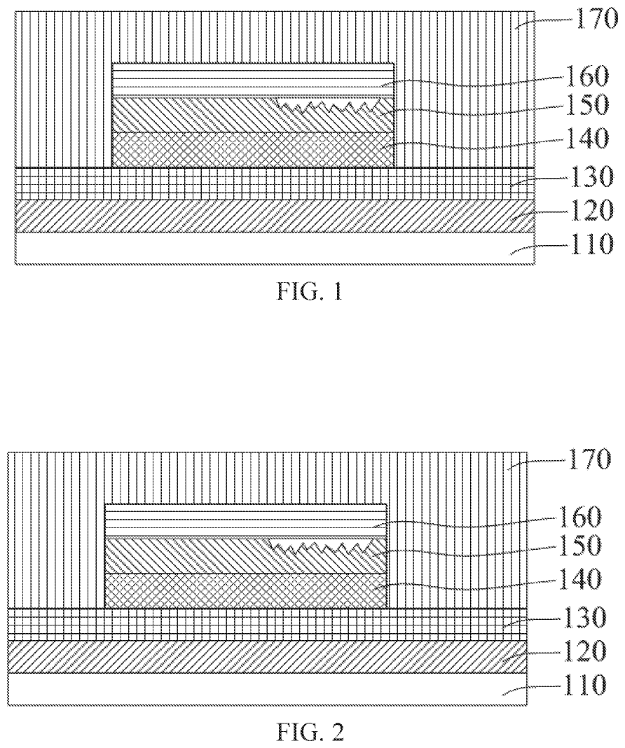

### DETAILED DESCRIPTION OF PREFERRED EMBODIMENTS

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc. are only directions with regard to the accompanying drawings. Therefore, the directional terms used for describing and illustrating the present disclosure are not intended to limit the present disclosure.

### First Embodiment

In the first embodiment, a method for manufacturing a flexible organic light emitting diode (OLED) display is provided, and includes:

a step 10 of forming an active array layer 220 on a flexible substrate 210, wherein a gate (not shown), a source 221, and a drain 222 are formed on the active array layer 220;

a step 20 of forming a planarization layer 230 on the active array layer 220;

a step 30 of performing photolithography on the planarization layer 230, to form at least a portion of an upper surface of the planarization layer 230 into an uneven surface 231;

a step 40 of forming an anode layer 240 on the uneven surface of the planarization layer 230;

a step 50 of forming an organic light emitting layer 250 on the anode layer 240;

a step 60 of forming a cathode layer 260 on the organic light emitting layer 250; and

a step 70 of forming a protective layer 270 on the cathode layer 260 and the planarization layer 230 to cover the cathode layer 260 and the planarization layer 230.

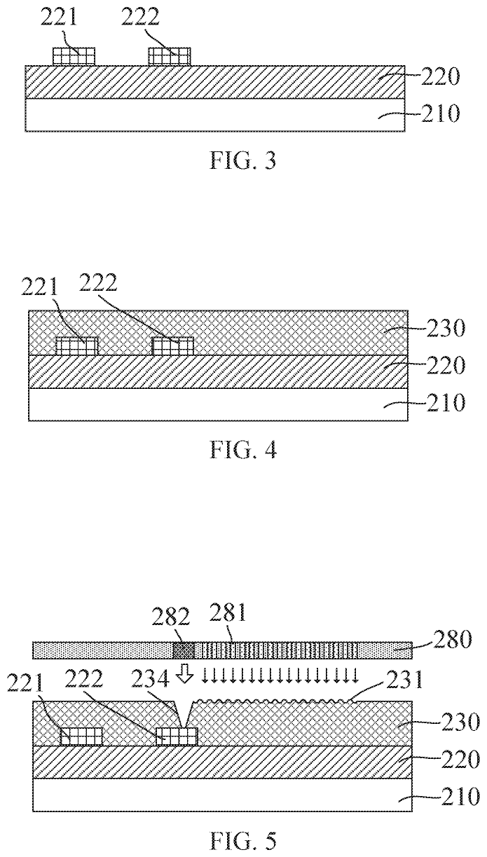

Refer to FIG. 3, which is a schematic diagram of the step S10 in a method for manufacturing a flexible OLED display 1 in accordance with an embodiment of the present disclosure.

In the step 10, the active array layer 220 is formed on the flexible substrate 210, wherein the gate (not shown), the source 221, and the drain 222 are formed on the active array layer 220.

As shown in FIG. 3, the active array layer 220 is sequentially formed on the flexible substrate 210. The active array layer 220 (or as known as the thin-film transistor layer) has a plurality of thin film transistors including the gate (not shown), the source 221 and the drain 222. The active array layer 220 includes an active layer for forming a channel, a gate insulating layer, a first metal layer, an interlayer insulating layer, and a second metal layer.

Refer to FIG. 4, which is a schematic diagram of the step S20 in a method for manufacturing a flexible OLED display 1 in accordance with the same embodiment of the present disclosure.

In the step 20, the planarization layer 230 is formed on the active array layer 220.

Material of the planarization layer 230 mainly includes (1) an inorganic material, which is an electrical insulator, such as silicon dioxide (SiO₂) or silicon nitride (SiNx), and mainly used as the top of a conductive metal substrate; (2) an organic polymer, such as acrylic, melamine or polyurethane polymer; or (3) other organic-inorganic hybrid composites.

FIG. 5 is a schematic diagram of a step S31 in a method for manufacturing a flexible OLED display 1 in accordance with the same embodiment of the present disclosure.

In the step 30, photolithography is performed on the planarization layer 230, to form at least a portion of the upper surface of the planarization layer 230 into the uneven surface 231. Specifically, in the present embodiment, the step 30 includes a step 31 and a step 33, in which the photolithography is performed on the planarization layer 230, by using a photomask 280 having a semi-transmissive array structure 281 to form at least a portion of the upper surface of the planarization layer 230 into the uneven surface 231 and to form a via hole 234 in the planarization layer 230 at the same time, wherein the via hole 234 penetrates through the planarization layer 230 to the source 221 and the drain 222. The via hole 234 as shown in FIG. 5 extends through the planarization layer 230 to the drain 222. However, the via hole 234 may also alternatively extend through the planarization layer 230 to the source 221, and claim scope of the present disclosure should not be limited thereby.

When the photolithography is performed on the planarization layer 230, a halftone mask is used as the mask 280. The semi-transmissive array structure 281 of the halftone mask 280 is used to form the uneven surface 231 on the planarization layer 230. The halftone mask 280 may also have a fully transparent region 282 for forming the via hole 234 in the planarization layer 230.

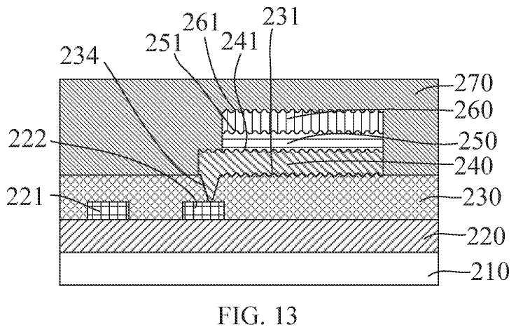

An example is provided herein. If pixels of the manufactured flexible OLED display 1 is designed as diamond pixels, as shown in FIG. 11, the largest pixels are blue pixels (B), and the second largest pixels are red pixels (R), and the smallest pixels are green pixels (G), the corresponding photomask 280 can be designed as shown in FIG. 12, wherein pixel regions correspond to the semi-transmissive array structures 281 for forming the uneven surface 231 on the planarization 230, and one corner of each pixel region corresponds to the fully transparent region 282 for forming the via hole 234 in the planarization layer 230. The semi-transmissive array structures and the pixel regions have a diameter of about 1 to 2 μm. However, other types of pixel designs are alternatively applicable to the method for manufacturing the flexible OLED display 1 of the present disclosure, and the claim scope of the present disclosure should not be limited thereby.

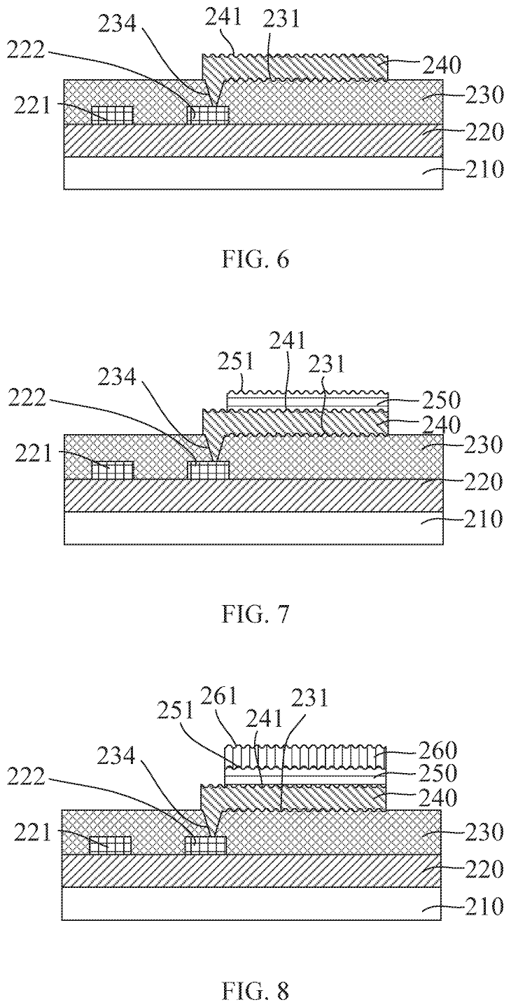

FIG. 6 is a schematic diagram of the step S40 in a method for manufacturing a flexible OLED display 1 in accordance with the same embodiment of the present disclosure.

In the step 40, the anode layer 240 is formed on the uneven surface 231 of the planarization layer 230. Specifically, the anode layer 240 covers a surface of the unevenness 231 of the planarization layer 230 and the via hole 234, and is electrically connected to the source 221 or the drain 222 through the via hole 234.

Because the anode layer 240 is formed on the uneven surface 231 of the planarization layer 230 (also referred to as a first uneven surface 231), and an upper surface of the anode layer 240 (opposite to a side adjacent to the planarization layer 230) is formed into another uneven surface 241 (also referred to as a second uneven surface 241).

FIG. 7 is a schematic diagram of a step 50 in a method for manufacturing a flexible OLED display 1 in accordance with the same embodiment of the present invention.

In the step 50, the organic light emitting layer 250 is formed on the anode layer 240. In general, the organic light emitting display layer 250 includes an electron transport layer, an organic light emitting layer, a hole transport layer, and the like. Because the organic light emitting display layer 250 is formed on the uneven surface 241 of the anode layer 240 (also referred to as the second uneven surface 241), an upper surface of the organic light emitting display layer 250 (opposite to a side adjacent to the anode layer 240) is formed into another uneven surface 251 (also referred to as a third uneven surface 251).

FIG. 8 is a schematic diagram of a step S60 in a method for manufacturing a flexible organic light emitting diode display 1 in accordance with the same embodiment of the present disclosure.

In the step 60, the cathode layer 260 is formed on the organic light emitting layer 250. Because the cathode layer 260 is formed on the uneven surface 251 of the organic light emitting display layer 250 (also referred to as the third uneven surface 251), an upper surface of the cathode layer 260 (opposite to a side adjacent to the organic light emitting display layer 250) is formed into another uneven surface 261 (also referred to as a fourth uneven surface 261).

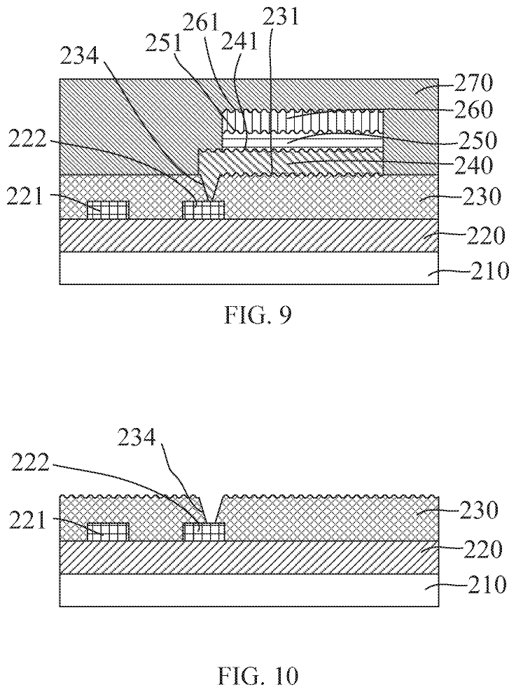

FIG. 9 is a schematic diagram of a step 70 in a method for manufacturing a flexible OLED display in accordance with the same embodiment of the present disclosure.

In the step 70, a protective layer 270 is formed on the cathode layer 260 and the planarization layer 230 to cover the cathode layer 260 and the planarization layer 230 to isolate components inside the flexible OLED display 1 from external environment.

The method for manufacturing the flexible OLED display 1 disclosed in the present disclosure solves a problem that peeling is liable to occur to the flexible OLED display 1 when the flexible OLED display 1 is bent. In the present embodiment, by using a halftone photomask for performing photolithography on the planarization layer, normal flat surfaces are replaced by an uneven surface formed between the planarization layer and the anode layer, an uneven surface between the anode layer and the organic light emitting layer, and an uneven surface between the cathode layer and the organic light emitting layer, for increasing a contact area between the planarization layer and the anode layer, and a contact area between the organic light emitting layer and the cathode and the anode, thereby effectively enhancing the adhesion between the planarization layer and the anode layer and the adhesion between the OLED light emitting layer and the cathode layer and the anode layer, to improve the peeling occurring in the OLED light emitting layer, and to improve impact resistance and bending resistance of the flexible screen. At the same time, the solution is compatible with conventional technology.

### Second Embodiment

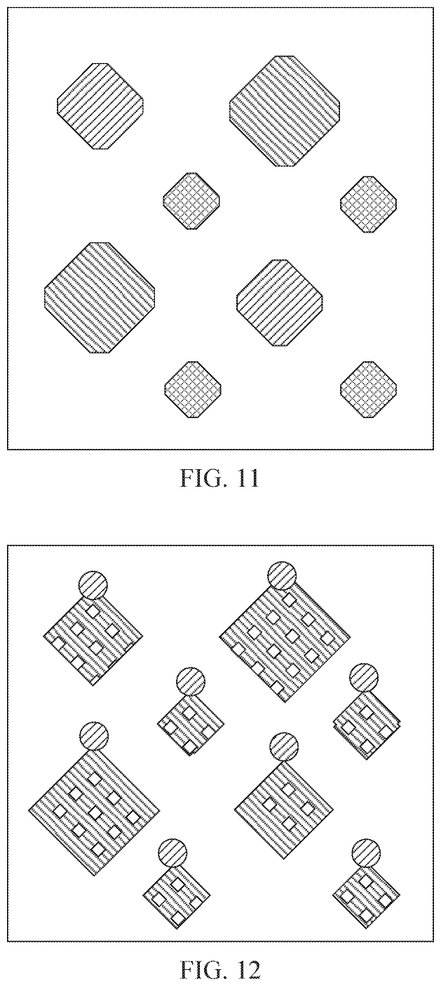

In the second embodiment, a method for manufacturing a flexible organic light emitting diode (OLED) display 1 is provided. The manufacturing method in the second embodiment is substantially the same as the manufacturing method in the first embodiment, and the only difference is that the step 30 is implemented by a step 32: the photolithography is performed on a planarization layer, by using a photomask having a semi-transmissive array structure to form an entire upper surface of the planarization layer into an uneven surface, as shown in FIG. 10.

More specifically, in the present embodiment, the step 30 includes the step 32 and the step 33: the photolithography, such as photoetching or ashing, is performed on a planarization layer 230 to form an entire upper surface of the planarization layer 230 into an uneven surface 231 and to form a via hole 234 in the planarization layer 230 at the same time, wherein the via hole 234 penetrates through the planarization layer 230 to a source 221 and a drain 222. The via hole 234 as shown in FIG. 5 extends through the planarization layer 230 to the drain 222. However, via hole 234 may also alternatively extend through the planarization layer 230 to the source 221, and the claim scope of the present disclosure should not be limited thereby. Remaining steps of the second embodiment are the same as those of the first embodiment.

### Third Embodiment

A flexible organic light emitting diode (OLED) display 1 is provided in the third embodiment.

FIG. 13 is a side view of a flexible OLED display in accordance with the same embodiment of the present disclosure.

As shown in FIG. 13, the flexible OLED display 1 includes:

a flexible substrate 210;

an active array layer 220 disposed on the flexible substrate 210, wherein a gate (not shown), a source 221, and a drain 222 formed on the active array layer 220;

a planarization layer 230 disposed on the active array layer 220, wherein at least a portion of an upper surface of the planarization layer 230 includes a first uneven surface 231, wherein a via hole 234 is formed in the planarization layer 230, and the via hole 234 penetrates through the planarization layer 230 to the source 221 and the drain 222;

an anode layer 240 disposed on the first uneven surface 231 of the planarization layer 230, wherein an upper surface of the anode layer 240 includes a second uneven surface 241;

an organic light emitting layer 250 disposed on the second uneven surface 241 of the anode layer 250, wherein an upper surface of the organic light emitting layer 250 includes a third uneven surface 251;

a cathode layer 260 disposed on the third uneven surface 251 of the organic light emitting layer 250, wherein an upper surface of the cathode layer 260 includes a fourth uneven surface 261;

and a protective layer 270 disposed on the cathode layer 260 and the planarization layer 230.

In the flexible OLED display 1 as shown in FIG. 13, only a portion of an upper surface of the planarization layer 230 is formed into a first uneven surface 231. However, in this embodiment, a partial upper surface of the planarization layer 230 may be formed into the first uneven surface 231, or the entire upper surface of the planarization layer 230 may be formed into the first uneven surface 231. The claim scope of the present disclosure should not be limited thereby.

In this embodiment, the diameters of the first uneven surface 231, the second uneven surface 241, the third uneven surface 251, and the fourth uneven surface 261 range from about 1p m to about 2 μm. However, the sizes of the diameters may be adjusted as needed, and should not limit the scope of the present disclosure.

In the flexible OLED display and the manufacturing method thereof of the present disclosure, normal flat surfaces are replaced by an uneven surface formed between the planarization layer and the anode layer, an uneven surface between the anode layer and the organic light emitting layer, and an uneven surface between the cathode layer and the organic light emitting layer, for increasing a contact area between the planarization layer and the anode layer, and a contact area between the organic light emitting layer and the cathode and the anode, thereby effectively enhancing the adhesion between the planarization layer and the anode layer and the adhesion between the OLED light emitting layer and the cathode layer and the anode layer, to improve the peeling occurring in the OLED light emitting layer, and to improve impact resistance and bending resistance of the flexible screen. At the same time, the solution is compatible with conventional technology.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

What is claimed is:

1. A method for manufacturing a flexible organic light emitting diode (OLED) display, comprising:
a step 10 of forming an active array layer on a flexible substrate, wherein a gate, a source, and a drain are formed on the active array layer;
a step 20 of forming a planarization layer on the active array layer;
a step 30 of performing photolithography on the planarization layer, to form at least a portion of an upper surface of the planarization layer into an uneven surface;
a step 40 of forming an anode layer on the uneven surface of the planarization layer;
a step 50 of forming an organic light emitting layer on the anode layer;
a step 60 of forming a cathode layer on the organic light emitting layer; and
a step 70 of forming a protective layer on the cathode layer and the planarization layer to cover the cathode layer and the planarization layer.

2. The manufacturing method as claimed in claim 1, wherein the step 30 comprises:
a step 31 of performing the photolithography on the planarization layer, by using a photomask having a semi-transmissive array structure to form at least the portion of the upper surface of the planarization layer into the uneven surface.

3. The manufacturing method as claimed in claim 2, wherein the photomask having a semi-transmissive array structure is a half-tone photomask.

4. The manufacturing method as claimed in claim 2, wherein the semi-transmissive array structure has a diameter of 1 to 2 μm.

5. The manufacturing method as claimed in claim 1, wherein the step 30 comprises:
a step 32 of performing the photolithography on the planarization layer, by using a photomask having a semi-transmissive array structure to form the entire upper surface of the planarization layer into the uneven surface.

6. The manufacturing method according to claim 1, wherein the step 30 comprises:
a step 33 of performing the photolithography on the planarization layer, to form at least the portion of the upper surface of the planarization layer into the uneven surface and to form a via hole in the planarization layer, wherein the via hole penetrates through the planarization layer to the source and the drain.

7. A flexible organic light emitting diode (OLED) display comprising:
a flexible substrate;
an active array layer disposed on the flexible substrate, wherein a gate, a source, and a drain formed on the active array layer;
a planarization layer disposed on the active array layer, wherein at least a portion of an upper surface of the planarization layer includes a first uneven surface;
an anode layer disposed on the first uneven surface of the planarization layer, wherein an upper surface of the anode layer includes a second uneven surface;
an organic light emitting layer disposed on the second uneven surface of the anode layer, wherein an upper surface of the organic light emitting layer includes a third uneven surface;
a cathode layer disposed on the third uneven surface of the organic light emitting layer, wherein an upper surface of the cathode layer includes a fourth uneven surface; and
a protective layer disposed on the cathode layer and the planarization layer.

8. The flexible OLED display of claim 7, wherein only the portion of the upper surface of the planarization layer includes the first uneven surface.

9. The flexible OLED display of claim 7, wherein the entire upper surface of the planarization layer is the first uneven surface.

10. The flexible OLED display of claim 7, wherein the first uneven surface, the second uneven surface, the third uneven surface, and the fourth uneven surface respectively have diameters of 1 to 2 μm.

11. The flexible OLED display of claim 7, wherein a via hole is formed in the planarization layer, and the via hole penetrates through the planarization layer to the source or the drain.

12. A method for manufacturing a flexible organic light emitting diode (OLED) display, comprising:
a step 10 of forming an active array layer on a flexible substrate, wherein a gate, a source, and a drain are formed on the active array layer;
a step 20 of forming a planarization layer on the active array layer;
a step 30 of performing photolithography on the planarization layer, to form at least a portion of an upper surface of the planarization layer into an uneven surface; wherein the step 30 comprises:
a step 31 of performing the photolithography on the planarization layer, by using a photomask having a semi-transmissive array structure to form at least the portion of the upper surface of the planarization layer into the uneven surface;
a step 40 of forming an anode layer on the uneven surface of the planarization layer;
a step 50 of forming an organic light emitting layer on the anode layer;
a step 60 of forming a cathode layer on the organic light emitting layer; and
a step 70 of forming a protective layer on the cathode layer and the planarization layer to cover the cathode layer and the planarization layer.

13. The manufacturing method as claimed in claim 12, wherein the photomask having a semi-transmissive array structure is a half-tone photomask.

14. The manufacturing method as claimed in claim 12, wherein the semi-transmissive array structure has a diameter of 1 to 2 μm.

15. The manufacturing method as claimed in claim 12, wherein the step 30 comprises:
a step 32 of performing the photolithography on the planarization layer, by using a photomask having a semi-transmissive array structure, to form the entire upper surface of the planarization layer into the uneven surface.

16. The manufacturing method according to claim 12, wherein the step S30 comprises:
a step 33 of performing the photolithography on the planarization layer, to form at least the portion of the upper surface of the planarization layer into the uneven surface and to form a via hole in the planarization layer, wherein the via hole penetrates through the planarization layer to the source and the drain.
